(19) United States
(12) Patent Application Publication
(10) Pub. No.: US 2023/0187230 A1
(43) Pub. Date: Jun. 15, 2023

(54) SUBSTRATE PROCESSING APPARATUS AND SUBSTRATE PROCESSING METHOD

(71) Applicant: SEMES CO., LTD., Cheonan-si (KR)

(72) Inventor: Eui Sang LIM, Cheonan-si (KR)

(73) Assignee: SEMES CO., LTD., Cheonan-si (KR)

(21) Appl. No.: 18/078,019

(22) Filed: Dec. 8, 2022

(30) Foreign Application Priority Data
Dec. 13, 2021 (KR) 10-2021-0177980

(51) Int. Cl. H01L 21/67; H01L 21/687

(52) U.S. Cl. CPC H01L 21/67034; H01L 21/67103; H01L 21/6719; H01L 21/68742

(57) ABSTRACT

A substrate processing apparatus includes a chamber body providing a processing space for drying a substrate with a drying fluid in a supercritical state, a substrate support chuck supporting the substrate in the processing space, a fluid supply unit including a fluid supply line configured to supply the drying fluid to the processing space, and a supply line heating unit configured to heat the fluid supply line.

### CROSS REFERENCE TO RELATED APPLICATION

The present application claims priority to Korean Patent Application No. 10-2021-0177980, filed Dec. 12, 2021, the entire contents of which are incorporated by reference herein for all purposes.

### BACKGROUND OF THE INVENTION

### Field of the Invention

An embodiment of the present disclosure relates to a substrate processing apparatus and a substrate processing method. More specifically, an embodiment of the present disclosure relates to an apparatus and a method that are capable of processing a substrate by using a fluid in a supercritical state.

### Description of the Related Art

Generally, a semiconductor is manufactured by forming a circuit pattern on a substrate such as a silicon wafer and so on by performing various processes including a photo-lithography process. During this manufacturing process, various foreign substances such as particles, organic contaminants, metal impurities, and so on are generated. Further, these foreign substances cause defects in the substrate and act as a factor directly affecting the yield of a semiconductor device. Therefore, in a semiconductor manufacturing process, a cleaning process for removing foreign substances from the substrate is necessarily accompanied.

Generally, cleaning of the substrate is performed by chemically removing foreign substances on the substrate, then washing the substrate with pure water, and then drying the substrate by using isopropyl alcohol (IPA). However, in the cleaning process, when the semiconductor device has a fine circuit pattern, drying efficiency of the substrate is low and also a pattern collapse in which the circuit pattern is damaged during the drying process frequently occurs, so that the cleaning process is not suitable for a semiconductor device having a line width equal to or less than 30 nm.

Therefore, recently, research related to a process of drying a substrate by using a supercritical fluid that is capable of compensating for the disadvantages described above has been actively conducted.

### Document of Related Art

(Patent Document 1) Korean Patent No. 10-2225957 (Mar. 11, 2021)

(Patent Document 2) Korean Patent Application Publication No. 10-2021-0066204 (Jun. 7, 2021)

### SUMMARY OF THE PRESENT DISCLOSURE

Accordingly, the present disclosure has been made keeping in mind the above problems occurring in the related art, and an objective of an embodiment of the present disclosure is to provide a substrate processing apparatus and a substrate processing method that are capable of minimizing a temperature deviation of a fluid used for performing a supercritical process.

In addition, another objective of the present disclosure is to provide a substrate processing apparatus and a substrate processing method that are capable of more consistently maintaining a substrate processing condition according to performance of a supercritical process.

In addition, still another objective of the present disclosure is to provide a substrate processing apparatus and a substrate processing method that are capable of reducing a time required for a supercritical process.

The technical problems to be solved by the present disclosure are not limited to the above-mentioned problems and other problems which are not mentioned will be clearly understood by those skilled in the art from the following description.

According to an embodiment of the present disclosure, there is provided a substrate processing apparatus including: a chamber body providing a processing space for drying a substrate with a drying fluid in a supercritical state; a substrate support chuck supporting the substrate in the processing space; a fluid supply unit including a fluid supply line configured to supply the drying fluid to the processing space; and a supply line heating unit configured to heat the fluid supply line.

According to an embodiment of the present disclosure, there is provided a substrate processing apparatus including: a chamber body providing a processing space for drying a substrate with a drying fluid in a supercritical state; a chamber heater configured to heat the processing space to a temperature equal to or more than a critical temperature of the drying fluid; a substrate support unit supporting the substrate in the processing space; a fluid supply unit which has a fluid supply line that is configured to supply the drying fluid to the processing space and which has a filter and a supply line opening and closing valve that are separately provided on the fluid supply line; a vent unit connected to the processing space; and a supply line heating unit which has a fluid injection line that is configured to inject a heating fluid into the fluid supply line and which has an injection line heater and an injection line opening and closing valve that are separately provided on the fluid injection line, in which the fluid injection line is connected on the fluid supply line at an upstream side with respect to the filter, wherein the supply line heating unit is configured to be operated so that the fluid supply line is heated by allowing the heating fluid in which a temperature thereof is increased in an idle mode to flow to the fluid supply line, and the fluid supply unit is configured such that the supply line opening and closing valve is opened so that the heating fluid in which the temperature thereof is increased in the idle mode is capable of being supplied to the processing space along the fluid supply line.

According to an embodiment of the present disclosure, there is provided a substrate processing method of drying a substrate in a processing space of a chamber body with a drying fluid in a supercritical state, the substrate processing method including: performing a first process in which a fluid supply line connected to the processing space is heated in an idle mode; and performing a second process in which a pressure of the processing space is increased by supplying the drying fluid to the processing space through the fluid supply line and the substrate is dried in a supercritical process mode.

The technical solutions will be more specifically and clearly described with reference to the embodiments to be described below and the drawings. In addition to the above-mentioned technical solutions, various technical solutions will be additionally provided.

According an embodiment of the present disclosure, since the fluid supply line of the fluid supply unit is heated by the supply line heating unit, a temperature of the processing fluid which flows to the processing space of the chamber body along the fluid supply line so as to perform the supercritical process may be adjusted to a temperature in a predetermined range by a thermal movement. Therefore, when the supercritical process is performed, the processing fluid in which the temperature thereof is adjusted to the temperature in the predetermined range is supplied to the processing space, so that the creation time of the supercritical atmosphere may be reduced. In addition, since the temperature deviation of the processing fluid due to the temperature drop of the fluid supply line or the like is minimized, damage acting on the substrate may be reduced and the substrate processing condition may be more consistently maintained.

The effects of the present disclosure are not limited to the above-mentioned effects, and other effects which are not mentioned above may be clearly understood by those skilled in the art from the present specification and the accompanying drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view illustrating a substrate processing apparatus according to an embodiment of the present disclosure;

FIG. 2 is a cross-sectional view illustrating a first process chamber illustrated in FIG. 1;

FIG. 3 is a phase diagram of carbon dioxide;

FIG. 4 is a view illustrating a configuration of an example of a second process chamber illustrated in FIG. 1;

FIG. 5 is a flowchart illustrating an operation of the second process chamber illustrated in FIG. 4;

FIG. 6 is a view illustrating a configuration of a fluid supply module of the substrate processing apparatus according to an embodiment of the present disclosure; and

FIGS. 7 and 8 are views respectively illustrating configurations of modification examples of the second process chamber of the substrate processing apparatus according to an embodiment of the present disclosure.

### DETAILED DESCRIPTION OF THE INVENTION

Hereinbelow, an embodiment of the present disclosure will be described in detail with reference to the accompanying drawings such that the present disclosure can be easily embodied by one of ordinary skill in the art to which the present disclosure belongs. However, the present disclosure is not limited to the embodiment described herein and may be embodied in many different forms.

In describing the embodiment of the present disclosure, a detailed description of known function or configuration related to the present disclosure will be omitted when it may obscure the subject matter of the present disclosure, and the same reference numerals will be used throughout the drawings to refer to the elements or parts with same or similar function or operation.

Further, technical terms, as will be mentioned hereinafter, are terms defined in consideration of their function in the present disclosure, which may be changed according to the intention of a user, practice, or the like. Therefore, the terms should be defined on the basis of the contents of this specification. Unless the context clearly indicates otherwise, it will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. In addition, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

In the drawings, the shapes and sizes of parts and thicknesses of lines may be exaggerated for convenience of understanding.

A substrate processing apparatus according to an embodiment of the present disclosure may perform a supercritical process and so on. The supercritical process refers to a process in which a substrate is processed by using a fluid that is in a supercritical state. For example, as a process for the substrate, the supercritical process may be a supercritical cleaning process performing cleaning by using a fluid in the supercritical state, or may be a supercritical drying process performing drying. Of course, the supercritical process is not limited to an example described above.

The substrate processed by the substrate processing apparatus according to an embodiment of the present disclosure should be understood as a comprehensive concept. Therefore, the substrate includes various wafers including a silicon wafer, and includes an organic substrate and a glass substrate. Further, the substrate includes a substrate used for manufacturing a semiconductor device, a display, and an object having a circuit pattern formed on a thin film.

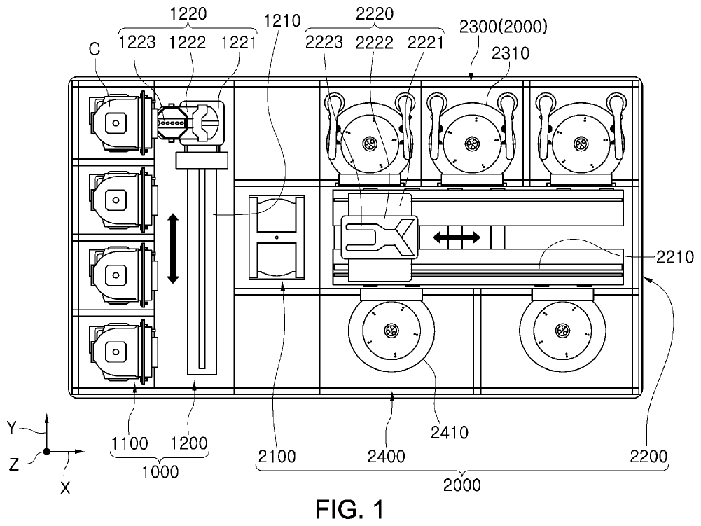

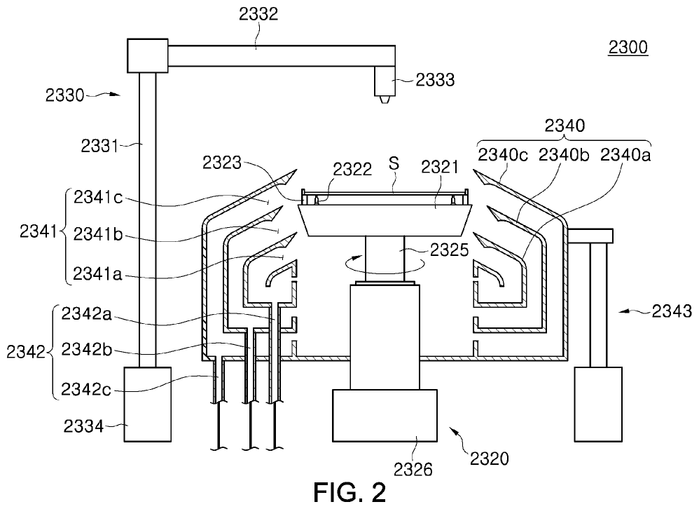

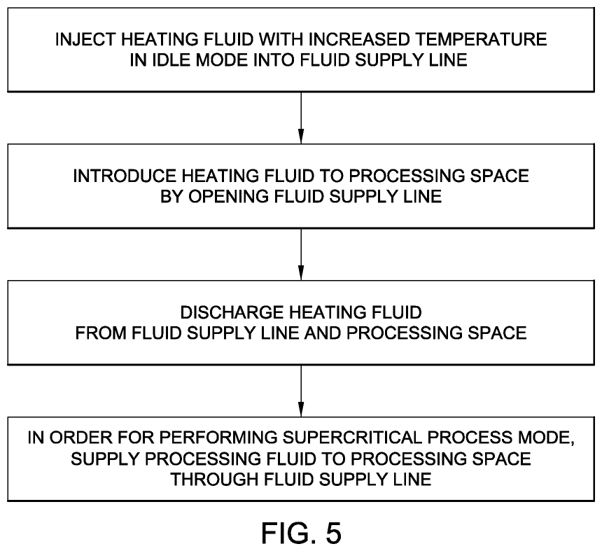

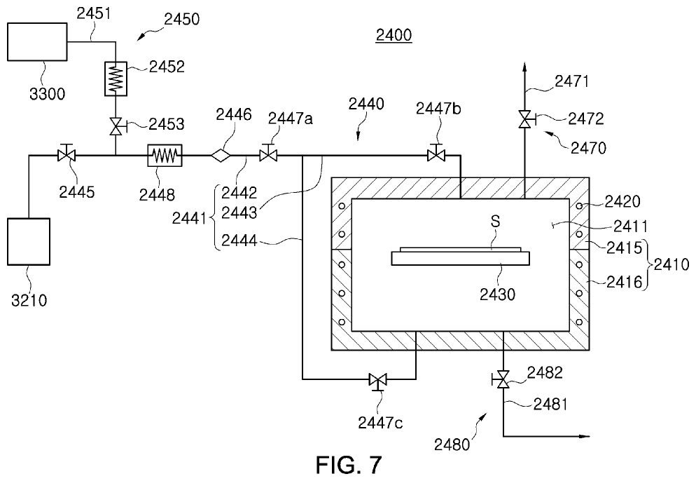

The substrate processing apparatus according to an embodiment of the present disclosure may include an index module (see reference numeral 1000 in FIG. 1), a process module (see reference numeral 2000 in FIG. 1), and a fluid supply module (see reference numeral 3000 in FIG. 6). The index module may transfer a substrate (see reference character S in FIG. 2 and FIG. 4) from the outside to the process module. The process module may process the substrate by using a fluid. The fluid supply module may supply a fluid to the process module.

FIG. 1 is a plan view schematically illustrating a substrate processing apparatus according to an embodiment of the present disclosure. The configuration and so on of the index module and the process module are illustrated in FIG. 1. Referring to FIG. 1, the index module 1000 may be an equipment front end module (EFEM) that includes a load port 1100 and an index unit 1200. The process module 2000 may include a buffer chamber 2100, a transfer chamber 2200, a first process chamber 2300, and a second process chamber 2400.

The load port 1100, the index unit 1200, and the process module 2000 may be sequentially disposed in a row. A direction in which the load port 1100, the index unit 1200, and the process module 2000 are sequentially disposed is defined as a first direction X. In addition, when viewed from above, a direction perpendicular to the first direction X is defined as a second direction Y, and a direction perpendicular to both the first direction X and the second direction Y is defined as a third direction Z.

The load port 1100 may be configured such that a plurality of load ports 1100 is sequentially disposed in a row along the second direction Y. The substrate may be accommodated in a container C. The container C may be a front opening unified pod (FOUP). The container C may be transferred from the outside and then may be loaded on the load port 1100, or may be unloaded from the load port 1100 and then may be transferred to the outside. The container C may be transferred between the load ports 1100 of the substrate processing apparatuses by a container transferring apparatus such as an overhead hoist transport (OHT), an automated guided vehicle (AGV), a rail guided vehicle (RGV), or the like, or by a worker.

The index unit 1200 may transfer the substrate between the process module 2000 and the container C that is loaded on the load port 1100. The index unit 1200 may include an index rail 1210 and an index robot 1220. The index rail 1210 may provide a path in which the index robot 1220 is moved. The index rail 1210 may be provided such that a longitudinal direction of the index rail 1210 is aligned with the second direction Y. The index robot 1220 may transfer the substrate.

The index robot 1220 may include a robot base 1221, a robot body 1222, and a robot arm 1223. The robot base 1221 may be moved along the index rail 1210. The robot body 1222 is capable of being moved on the robot base 1221 along the third direction Z, and may also be provided such that the robot base 1221 is capable of being rotated with respect to an axis of the third direction Z. The robot arm 1223 may be provided at the robot body 122 such that the robot arm 1223 is capable of being moved forward and backward. A robot hand may be provided at a first end of the robot arm 1223, so that the robot aim 1223 is capable of holding the substrate or is capable of releasing the holding of the substrate. For example, the index robot 1220 may be provided with a plurality of robot arms 1223. Further, the plurality of robot arms 1223 may be disposed such that the plurality of robot arms 1223 is stacked along the third direction Z, and may be individually driven. Since the robot base 1221 is moved along the index rail 1210 and the robot body 1222 and the robot arm 1223 are operated, such an index robot 1220 may transfer the substrate between the container C and the process module 2000.

The index module 1000, the buffer chamber 2100, and the transfer chamber 2200 may be sequentially disposed along the first direction X. The transfer chamber 2200 may be arranged such that a longitudinal direction of the transfer chamber 2200 is aligned with the first direction X. The first process chamber 2300 and the second process chamber 2400 may be arranged at sides of the transfer chamber 2200 in the second direction Y. For example, the first process chamber 2300 and the second process chamber 2400 may be arranged at the opposite sides of the transfer chamber 2200 such that the transfer chamber 2200 is interposed therebetween and the first process chamber 2300 and the second process chamber 2400 are facing each other. The arrangement of the chambers 2100, 2200, 2300, and 2400 is not limited thereto, and may be appropriately changed according to various elements such as a footprint, process efficiency, and so on.

The buffer chamber 2100 may provide a space in which the substrate transferred between the index module 1000 and the process module 2000 temporarily stays. For example, when the index robot 1220 transfers the substrate from the container C to the buffer chamber 2100, a transferring robot 2220 of the transfer chamber 2200 may transfer the substrate from the buffer chamber 2100 to the first process chamber 2300 or to the second process chamber 2400.

The transfer chamber 2200 may transfer the substrate between the buffer chamber 2100, the first process chamber 2300, and the second process chamber 2400 that are disposed around the transfer chamber 2200. The transfer chamber 2200 may include a transferring rail 2210 and the transferring robot 2220. The transferring rail 2210 may provide a path in which the transferring robot 2220 is moved. The transferring rail 2210 may be provided such that the transferring rail 2210 is aligned with the first direction X. The transferring robot 2220 may transfer the substrate.

The transferring robot 2220 may include a robot base 2221, a robot body 2222, and a robot arm 2223. Since the robot base 2221, the robot body 2222, and the robot arm 2223 of the transferring robot 2220 are similar to the robot base 1221, the robot body 1222, and the robot arm 1223 of the index robot 1220, so that detailed description thereof will be omitted. Since the robot base 2221 is moved along the transferring rail 2210 and the robot body 2222 and the robot arm 2223 are operated, such a transferring robot 2220 may transfer the substrate between buffer chamber 2100, the first process chamber 2300, and the second process chamber 2400.

The first process chamber 2300 and the second process chamber 2400 may perform different processes on the substrate. A first process performed in the first process chamber 2300 and a second process performed in the second process chamber 2400 may be processes that are sequentially performed with each other. For example, the first process including a chemical process, a cleaning process, and a first drying process may be performed in the first process chamber 2300, and the second process which includes a second drying process and which is a process subsequent to the first process may be performed in the second process chamber 2400. The first drying process may be a wet drying process using an organic solvent, and the second drying process may be a supercritical drying process using a fluid in a supercritical state. According to situations, only one process selected from the first drying process and the second drying process may be performed. Of course, processes performed in the first process chamber 2300 and the second process chamber 2400 are not limited to an example described above.

FIG. 2 is a cross-sectional view schematically illustrating the first process chamber 2300 of the substrate processing apparatus according to an embodiment of the present disclosure. The first process chamber 2300 will be described with reference to FIG. 2. The first process chamber 2300 may include a housing (see reference numeral 2310 in FIG. 1), a substrate support unit 2320, a fluid supply unit 2330, and a processing vessel 2340. The housing 2310 may provide a processing space in which the first process is performed. The substrate support unit 2320 may support the substrate S in the processing space of the housing 2310. The fluid supply unit 2330 may provide a fluid for the first process to the substrate S that is supported by the substrate support unit 2320. The processing vessel 2340 may collect the fluid scattered from the substrate S while the first process is performed.

The substrate support unit 2320 of the first process chamber 2300 may include a spin head 2321, a plurality of chuck pins 2323, and rotation drive mechanisms 2325 and 2326. The spin head 2321 may be provided such that the spin head 2321 is capable of being rotated with respect to the axis of the third direction Z, and the rotation drive mechanisms 2325 and 2326 may rotate the spin head 2321. The spin head 2321 may include support pins 2322 supporting the substrate S (hereinafter, reference character thereof will be omitted), and the chuck pins 2323 may fix a position of the substrate that is supported by the support pins 2322.

The support pins 2322 may protrude from an upper surface of the spin head 2321 so that a lower surface of the substrate is supported, and may be disposed such that the support pins 2322 are spaced apart from each other. The chuck pins 2323 may be provided at the spin head 2321. Each of the chuck pins 2323 supports a circumference of the substrate in a contact manner at positions spaced apart from each other, so that the substrate is prevented from being separated from an original position. Specifically, the chuck pins 2323 may be moved to the outside from a center of the spin head 2321 by a pin drive mechanism and then may be positioned at a standby position, or may be moved from the outside to the center of the spin head 2321 and then may be positioned at a supporting position. When the substrate is loaded or unloaded with respect to the spin head 2321, the chuck pins 2323 may be moved to the standby position and may wait. Further, during performing the first process that is for processing the substrate that is loaded, the chuck pins 2323 may be moved to the supporting position and may support the substrate. The chuck pins 2323 and the pin drive mechanism may compose a substrate chuck.

The rotation drive mechanisms 2325 and 2326 may include a shaft member 2325 in the third direction Z, the shaft member 2325 to which the spin head 2321 is connected, and may include a driving motor 2326 rotating the shaft member 2325. When the spin head 2321 is rotated by the rotation drive mechanisms 2325 and 2326, the substrate in which the position of the substrate is fixed by the chuck pins 2323 may be rotated.

The fluid supply unit 2330 of the first process chamber 2300 may include an arm support 2331, a nozzle arm 2332, a nozzle 2333, and a support drive mechanism 2334 (i.e., a support drive actuator).

The processing vessel 2340 may be disposed at the processing space of the housing 2310, and may have a cup structure in which an accommodating space is provided. Further, the spin head 2321 may be disposed at the accommodating space. The arm support 2331 may be disposed outside the processing vessel 2340 in the processing space of the housing 2310, and may be provided such that a longitudinal direction of the arm support 2331 is aligned with the third direction Z. The nozzle arm 2332 may be coupled to an upper end portion of the arm support 2331, and may extend in a direction perpendicular to the third direction Z. The nozzle 2333 may be provided at an end portion of the nozzle arm 2332 such that a fluid is discharged downward. The support drive mechanism 2334 may be configured to perform at least one of a rotation function (rotation with respect to the axis of the third direction Z) of the arm support 2331 and a lifting function (lifting along the third direction Z) of the arm support 2331. When the support drive mechanism 2334 is operated, the nozzle 2333 may be moved (rotation movement and/or lifting movement).

According to such a fluid supply unit 2330, the nozzle 2333 is rotated around the arm support 2331 by the support drive mechanism 2334, so that the nozzle 2333 may be positioned at the standby position or a supplying position. At this point, the standby position of the nozzle 2333 may be a position where the nozzle 2333 deviates from a vertical upper portion of the spin head 2321, and the supplying position of the nozzle 2333 may be a position where the nozzle 2333 is disposed on the vertical upper portion of the spin head 2321 so that the fluid discharged from the nozzle 2333 is supplied to the substrate on the spin head 2321. When the substrate is loaded or unloaded with respect to the spin head 2321, the nozzle 2333 may be moved to the standby position and may wait. Further, during performing the first process for processing the substrate that is loaded, the nozzle 2333 may be moved to the supplying position and may supply the fluid to the upper surface of the substrate.

The first process chamber 2300 may be provided with a plurality of fluid supply units 2330 described above. The plurality of fluid supply units 2330 may supply fluids different from each other. For example, the fluids which are different from each other and which are supplied by the plurality of fluid supply units 2330 may be a cleaning agent, a rinsing agent, and an organic solvent. For example, the cleaning agent may be a hydrogen peroxide solution, a hydrogen peroxide solution mixed with ammonia, hydrochloric acid, or sulfuric acid, or a hydrofluoric acid solution. The rinsing agent may be pure water. The organic solvent may be isopropyl alcohol. Of course, the cleaning agent, the rinsing agent, and the organic solvent are not limited to these examples.

When the fluid is supplied from the nozzle 2333 to the upper surface of the substrate and the spin head 2321 is rotated, the fluid supplied to the substrate may be scattered from the substrate to the surroundings. The processing vessel 2340 may collect the fluid that is scattered as described above. The processing vessel 2340 may include a plurality of vessels. The plurality of vessels may collect the fluids that are different from each other, and the number of the vessels may be appropriately selected according to the number of fluids used in the first process. The processing vessel 2340 will be described on the basis of a situation in which the processing vessel 2340 is composed of three vessels.

The vessels which have cup structures and which compose the processing vessel 2340 may be disposed away from the center of the spin head 2321 in the order of a first vessel 2340a, a second vessel 2340b, and a third vessel 2340c. Each of the vessels 2340a, 2340b, and 2340c has different levels along the third direction Z, so that inlet ports 2341 are formed in the processing vessel 2340. The processing vessel 2340 may be provided in a structure capable of being lifted along the third direction Z so that any one of the inlet ports 2341a, 2341b, and 2341c is positioned at the same level as the substrate on the spin head 2321. For example, a lift drive mechanism 2343 may be connected to the third vessel 2340c. Each of the vessels 2340a, 2340b, and 2340c may be connected to collect lines 2342 through which the collected fluid is transferred to a regenerative apparatus.

An example of a process in which the first process is performed in the first process chamber 2300 is as follows.

When the substrate is brought into the processing space of the housing 2310 by the transferring robot 2220 and the substrate is loaded on the spin head 2321, the cleaning agent as a fluid is supplied on the upper surface of the substrate, and the substrate is rotated by the spin head 2321 so that the supplied cleaning agent is evenly spread over the upper surface of the substrate. Further, the processing vessel 2340 is lifted so that the first inlet port 2341a of the first vessel 2340a is positioned at the same level as the substrate. In this process, foreign substances on the substrate are removed by the cleaning agent, and the cleaning agent scattered from the substrate is collected to the first vessel 2340a.

When the chemical process removing foreign substances by the cleaning agent is finished, pure water as the rinsing agent is supplied to the upper surface of the substrate, and the processing vessel 2340 is lifted so that the second inlet port 2341b of the second vessel 2340b is positioned at the same level as the substrate. In this process, the cleaning agent that remains on the substrate is removed by pure water, and the pure water that is scattered from the substrate is collected to the second vessel 2340b.

When the cleaning process in which the cleaning agent is removed by the rinsing agent is finished, the organic solvent is supplied to the upper surface of the substrate, and the processing vessel 2340 is lifted so that the third inlet port 2341c of the third vessel 2340c is positioned at the same level as the substrate. Here, the first drying process in which the organic solvent replaces pure water is performed, and the organic solvent scattered from the substrate is collected to the third vessel 2340c.

In the second process chamber 2400, the second process including a supercritical drying process using a fluid that is in a supercritical state may be performed. The supercritical fluid refers to a fluid in a state in which there is no distinction between gaseous and liquid phases since a material reaches a critical state in which a temperature and a pressure of the material exceed a critical temperature and a critical pressure. The supercritical fluid may exhibit a molecular density similar to that of liquid and a viscosity similar to that of gas. Since the supercritical fluid may exhibit excellent properties relevant to diffusion, permeation, and dissolution, the supercritical fluid may be advantageous for chemical reactions. Further, since the supercritical fluid has a very low surface tension and an interfacial tension does not act on a fine structure, excellent drying efficiency may be secured and pattern collapse may be prevented when the supercritical fluid is used in a drying process for a substrate. Carbon dioxide may be used as a supercritical fluid in the supercritical drying process. Of course, the supercritical fluid is not limited to carbon dioxide.

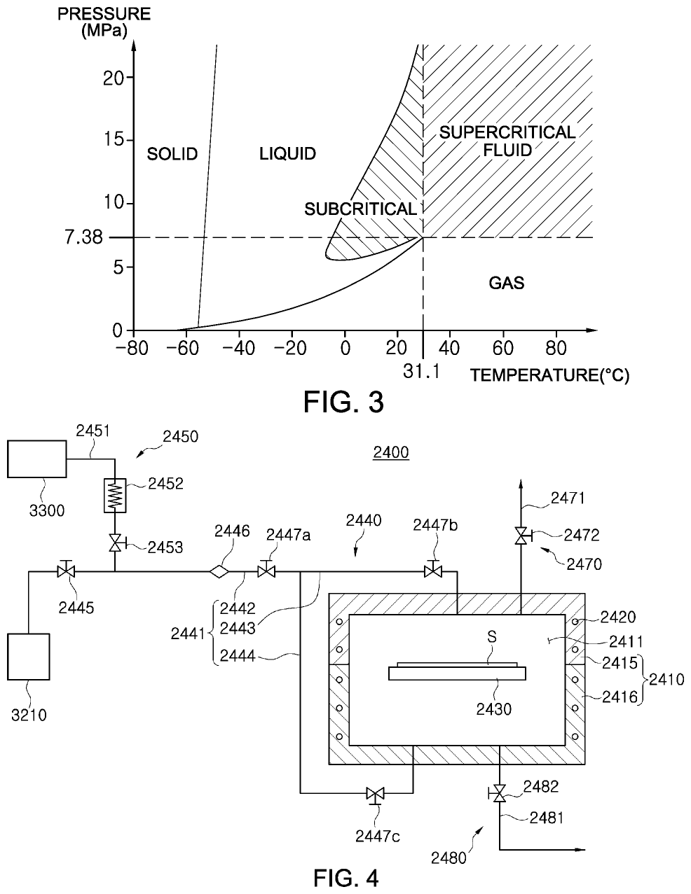

FIG. 3 is a phase diagram of carbon dioxide. Carbon dioxide becomes the supercritical state when a temperature of carbon dioxide is 31.1° C. or higher and a pressure of carbon dioxide is 7.38 Megapascal (MPa) or higher. Carbon dioxide exhibits non-toxic, nonflammable, and non-active properties. Carbon dioxide has a lower critical temperature and a lower critical pressure, so that solvency of carbon dioxide can be easily controlled. Further, carbon dioxide exhibits a diffusion coefficient that is 10 or 100 times lower than that of water or other organic solvents, and exhibits very small surface tension, so that carbon dioxide exhibits advantageous physical properties for a drying process. Further, carbon dioxide may be used by recycling byproducts of various chemical reactions, and may be re-used by recycling carbon dioxide used in the drying process. Therefore, the use of carbon dioxide reduces the burden of environmental pollution.

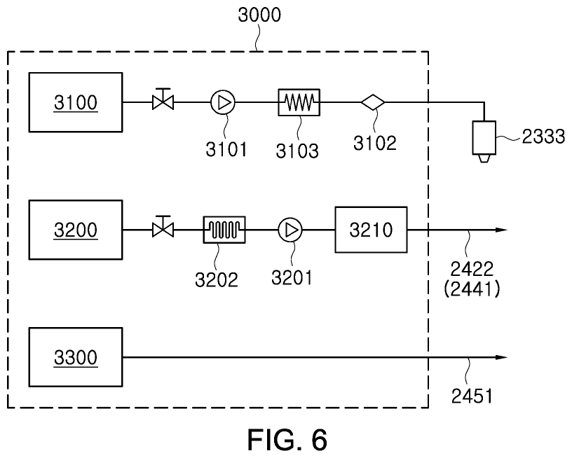

FIG. 4 is a view schematically illustrating a configuration of an example of the second process chamber 2400 of the substrate processing apparatus according to an embodiment of the present disclosure. FIG. 5 is a flowchart exemplarily illustrating an operation of the second process chamber 2400 illustrated in FIG. 4. The second process chamber 2400 will be described with reference to FIGS. 4 and 5. The second process chamber 2400 may include a chamber body 2410, a chamber heater 2420, a substrate support unit 2430 (i.e., a substrate support chuck), a fluid supply unit 2440, a vent unit 2470, a drain unit 2480, and a supply line heating unit 2450. The second process, which includes the supercritical drying process, maybe performed inside the chamber body 2410. In an inner portion of the chamber body 2410, the substrate may be processed by the fluid in the supercritical state. The fluid for performing the supercritical drying process may be supplied to the inner portion of the chamber body 2410 by the fluid supply unit 2440. Hereinafter, the fluid that becomes the supercritical state so as to perform the supercritical drying process will be referred to as a processing fluid (i.e., a drying fluid).

The chamber body 2410 may be configured such that the inner portion of the chamber body 2410 provides a processing space 2411 which is as a space where the second process is performed and which is blocked from the outside. Further, the chamber body 2410 may be provided such that the chamber body 2410 has a structure capable of sufficiently withstanding a high temperature and a high pressure for performing the supercritical drying process. The chamber body 2410 may include an upper body 2415 and a lower body 2416, and may provide the processing space 2411 by a combination of the upper body 2415 and the lower body 2416.

The upper body 2415 may be disposed at an upper side of the lower body 2416, and a position of the upper body 2415 may be fixed. The lower body 2416 may be lifted along the third direction Z with respect to the upper body 2415 by a body lift mechanism such as a cylinder. When the lower body 2416 is moved downward and the lower body 2416 is separated from the upper body 2415, the processing space 2411 of the chamber body 2410 is opened, so that the substrate may be brought into or out of the processing space 2411. When the lower body 2416 is moved upward and the lower body 2416 is in close contact with the upper body 2415, the processing space 2411 is sealed, so that the processing space 2411 may be blocked from the outside while the second process is performed.

The chamber heater 2420 may heat the processing space 2411 of the chamber body 2410, so that the processing fluid that is supplied into the processing space 2411 may be maintained in the supercritical state. The chamber heater 2420 may heat the processing fluid to a temperature equal to or more than the critical temperature. A supercritical atmosphere may be created in the processing space 2411 by the chamber heater 2420. For example, the chamber heater 2420 may be provided at a wall of the chamber body 2410.

The substrate support unit 2430 of the second process chamber 2400 is disposed at the processing space 2411 of the chamber body 2410.

The substrate support unit 2430 supports the substrate that is brought into the processing space 2411 by the transferring robot 2220. The substrate support unit 2430 may be provided in a fixed structure, or may be provided in a structure that is capable of being rotated.

The fluid supply unit 2440 of the second process chamber 2400 may include a fluid supply line 2441 configured to supply the processing fluid to the processing space 2411. In addition, the fluid supply unit 2440 may include a backflow prevention valve 2445 provided on the fluid supply line 2441, and may include a filter 2446, and a plurality of supply line opening and closing valves 2447a, 2447b, and 2447c. For example, the processing fluid in a gaseous state may be provided to the processing space 2411, and a phase of the processing fluid may be changed to the supercritical state in the processing space 2411. In an embodiment, the processing fluid in the supercritical state may be supplied to the processing space 2411.

The fluid supply line 2441 may include a main line 2442, a first branch line 2443, and a second branch line 2444. The first branch line 2443 and the second branch line 2444 may be branched from the main line 2442. The first branch line 2443 may be coupled to the upper body 2415 so that the processing fluid from the main line 2442 is capable of being supplied to the processing space 2411 from the upper side of the substrate that is supported by the substrate support unit 2430. The second branch line 2444 may be coupled to the lower body 2416 so that the processing fluid from the main line 2442 is capable of being supplied to the processing space 2411 from the lower side of the substrate that is supported by the substrate support unit 2430.

As the plurality of supply line opening and closing valves, the main valve 2447a, the first valve 2447b, and the second valve 2447c may be provided. The backflow prevention valve 2445, the filter 2446, and the main valve 2447a may be mounted on the main line 2442, the first valve 2447b may be mounted on the first branch line 2443, and the second valve 2447c may be mounted on the second branch line 2444. The backflow prevention valve 2445 may be disposed on the main line 2442 at a relatively upstream side, so that a situation in which the processing fluid does not flow to a downstream side (first and second branch line sides) along the main line 2442 and the backflow of the processing fluid occurs may be prevented. The main valve 2447a may be disposed on the main line 2442 at a relatively downstream side, so that the main line 2442 may be opened and closed and a flow rate of the processing fluid that flows to the first and second branch lines 2443 and 2444 from the main line 2442 may be adjusted. The filter 2446 may be disposed between the backflow prevention valve 2445 and the main valve 2447a, so that foreign substances may be removed from the processing fluid that flows along the main line 2442. The first valve 2447b may open and close the first branch line 2443, and may adjust the flow rate of the processing fluid that flows along the first branch line 2443. The second valve 2447c may open and close the second branch line 2444, and may adjust the flow rate of the processing fluid that flows along the second branch line 2444.

The vent unit 2470 may be connected to the processing space 2411, so that the processing fluid supplied to the processing space 2411 may be discharged in the gaseous state. The vent unit 2470 may discharge the processing fluid to the outside from the upper portion of the processing space 2411. The vent unit 2470 may include a vent line 2471 coupled to the upper body 2415, and may include a vent line opening and closing valve 2472 provided on the vent line 2471, the vent line opening and closing valve 2472 opening and closing the vent line 2471 and adjusting the flow rate of the processing fluid that flows along the vent line 2471.

The drain unit 2480 may be connected to the processing space 2411, so that the processing fluid supplied to the processing space 2411 may be discharged in the liquid state. The drain unit 2480 may discharge the processing fluid to the outside from the lower portion of the processing space 2411. The drain unit 2480 may include a drain line 2481 coupled to the lower body 2416, and may include a drain line opening and closing valve 2482 provided on the drain line 2481, the drain line opening and closing valve 2482 opening and closing the drain line 2481 and adjusting the flow rate of the processing fluid that flows along the drain line 2481.

The supply line heating unit 2450 may heat the fluid supply line 2441. A temperature of the processing fluid that flows along the heated fluid supply line 2441 may be adjusted to a predetermined range by heat supply from the heated fluid supply line 2441. For example, when the processing fluid is supplied to the processing space 2411 in the supercritical state, the temperature of the processing fluid during the process of supplying the processing fluid may be prevented from dropping below the critical temperature. Further, when the processing fluid is supplied to the processing space 2411 in the gaseous state, the temperature of the processing fluid during the process of supplying the processing fluid may be increased.

The second process chamber 2400 may be operated in a supercritical process mode that is for performing the supercritical drying process, and may be operated in an idle mode when the supercritical process mode is finished. The second process chamber 2400 may repeat the supercritical process mode and the idle mode.

For the operation in the supercritical process mode, after the substrate is supported by the substrate support unit 2430, the second process chamber 2400 performs a process in which the lower body 2416 that is moved downward is brought into close contact with the upper body 2415 so that the processing space 2411 is sealed. Further, the processing space 2411 in a sealed state is heated by the chamber heater 2420, and the processing fluid is supplied to the processing space 2411 in the sealed state by the fluid supply unit 2440, so that a process in which the supercritical atmosphere is created may be performed. In an initial stage of the supercritical process mode in which the processing fluid flows into the processing space 2411, the processing space 2411 may be in a state in which the temperature of the processing space 2411 does not reach the critical temperature of the processing fluid. In the idle mode, the supply line heating unit 2450 may increase the temperature of the fluid supply line 2441 to a predetermined level. Therefore, in the supercritical process mode, the processing fluid in which the temperature of the processing fluid is adjusted to the predetermined range of the temperature may be supplied to the processing space 2411, so that the creation time of the supercritical atmosphere may be reduced. In addition, by minimizing the temperature deviation of the processing fluid due to the temperature drop of the fluid supply line 2441, damage acting on the substrate may be reduced, and a substrate processing condition may be maintained more consistently while the supercritical drying process is repeatedly performed.

The supply line heating unit 2450 may heat the fluid supply line 2441 by using a heating fluid in which a temperature thereof is increased. Specifically, the supply line heating unit 2450 may flow the heating fluid in which the temperature thereof is increased to the fluid supply line 2441, thereby heating the fluid supply line 2441. The heating fluid may include an inert gas having a low reactivity, such as argon (Ar), helium (He), neon (Ne), nitrogen gas (N2), and so on. In consideration of a thermal energy transfer efficiency, an inert gas having high thermal conductivity may be used as the heating fluid. For example, the heating fluid may be nitrogen gas having higher thermal conductivity than a thermal conductivity of carbon dioxide that is the processing fluid.

The supply line heating unit 2450 may include a fluid injection line 2451 configured to inject the heating fluid into the fluid supply line 2441, an injection line heater 2452 configured to heat the heating fluid injected into the fluid supply line 2441 along the fluid injection line 2451, and an injection line opening and closing valve 2453 provided on the fluid injection line 2451, the injection line opening and closing valve 2453 opening and closing the fluid injection line 2451 and adjusting the flow rate of the heating fluid that flows along the fluid injection line 2451. The fluid injection line 2451 may be connected to the fluid supply line 2441, so that the heating fluid may be injected into the fluid supply line 2441. The injection line heater 2452 may be provided on the fluid injection line 2451, so that the heating fluid that flows along the fluid injection line 2451 may be heated. The injection line heater 2452 may be configured to perform a heating function by using an induction heating method, a direct heating method, and so on. As an example, the injection line heater 2452 may include a heating wire wound on the fluid injection line 2451, and may heat the heating fluid by heating the fluid injection line 2451 by the heating wire. As another example, the injection line heater 2452 may include a heating member disposed on an inner flow path of the fluid injection line 2451, and may heat the heating fluid by contacting the heating member to the heating fluid that flows along the fluid injection line 2451.

When the heating fluid in which the temperature thereof is increased by operating the supply line heating unit 2450 is injected into the fluid supply line 2441, the fluid supply unit 2440 may be operated such that the main valve 2447a, the first valve 2447b, and the second valve 2447c are opened. At this time, the heating fluid injected into the fluid supply line 2441 may be introduced into the processing space 2411. Accordingly, the heating fluid in which the temperature thereof is increased may be injected into the fluid supply line 2441, so that the main line 2442, the first branch line 2443, and the second branch line 2444 may be heated. Further, the heating fluid may be introduced into the processing space 2411 along the first branch line 2443 and the second branch line 244, so that the temperature and a humidity of the processing space 2411 may be adjusted to a level suitable for performing the second process.

The fluid injection line 2451 may be connected on the main line 2442 between the backflow prevention valve 2445 and the filter 2446, so that the heating fluid injected into the main line 2442 from the fluid injection line 2451 may be introduced into the processing space 2411 while being in a state in which foreign substances are removed by the filter 2446.

An example of a process in which the supercritical drying process is performed in the second process chamber 2400 is as follows.

In the idle mode before or after the supercritical process mode is performed, the processing space 2411 may be sealed, and the vent unit 2470 and the drain unit 2480 may be in a closed state. The idle mode is not limited thereto, so that the processing space 2411 may be opened and the vent unit 2470 may be in an opened state.

In the idle mode, by operating the supply line heating unit 2450, the heating fluid in which the temperature thereof is increased by a heating action of the injection line heater 2452 is injected into the main line 2442. Before operating the supply line heating unit 2450, the main valve 2447a, the first valve 2447b, and the second valve 2447c may be operated to be opened, so that the fluid supply line 2441 may be opened. The opening operation of the fluid supply line 2441 may be performed at the same time when the supply line heating unit 2450 is operated, or may be performed after the supply line heating unit 2450 is operated. At this time, the heating fluid in which the temperature thereof is increased heats the fluid supply line 2441 by allowing the heating fluid to flow along the fluid supply line 2441, and heats the processing space 2411 and adjusts the humidity of the processing space 2411 by being introduced into the processing space 2411. For example, the heating fluid may be injected into the fluid supply line 2441 while being in a state in which the temperature of the heating fluid is increased to a temperature equal to or more than the critical temperature of the processing fluid. The temperature of the fluid supply line 2441 and the temperature of the processing space 2411 are detected, and then the temperature of the heating fluid may be increased to a higher temperature on the basis of the detected temperature.

When the fluid supply line 2441 and the processing space 2411 are filled with the heating fluid in which the temperature thereof is increased, the operation of the supply line heating unit 2450 may be stopped. In an embodiment, the heating fluid may be discharged to the outside from the processing space 2411 by the vent unit 2470 and an additional injection of a fluid in which a temperature thereof is increased may be repeatedly performed without stopping the operation of the supply line heating unit 2450.

Next, prior to performing the supercritical process mode, the heating fluid may be discharged to the outside from the fluid supply line 2441 and the processing space 2411 by operating the vent unit 2470. Then, the supercritical process mode may be performed.

In the supercritical process mode, in a process in which the supercritical atmosphere is created by supplying the processing fluid into the processing space 2411, an inert gas as the heating fluid may be supplied together by operating the supply line heating unit 2450. At this time, the heating fluid that is injected into the fluid supply line 2441 may be or may not be in a state in which the temperature thereof is increased by the injection line heater 2452.

Since the temperature of the processing space 2411 in the initial stage of the supercritical process mode may not have reached to the critical temperature and the critical pressure of the processing fluid, the processing fluid may be firstly supplied through the second branch line 2444 and then may be supplied through the first branch line 2443 when the processing space 2411 reaches the critical state.

When the supercritical atmosphere is created, the organic solvent remaining on the substrate may be dissolved in the processing fluid that is in the supercritical state. When the organic solvent is sufficiently dissolved and the substrate is dried, the processing fluid may be discharged from the processing space 2411. Meanwhile, to increase dissolution efficiency of the organic solvent, supply and discharge of the processing fluid may be repeated.

FIG. 6 is a view schematically illustrating a configuration of the fluid supply module 3000 of the substrate processing apparatus according to an embodiment of the present disclosure.

Referring to FIG. 6, the fluid supply module 3000 may include a first tank 3100 in which a fluid to be provided to the nozzle 2333 of the first process chamber 2300 is stored, a second tank 3200 the processing fluid to be provided to the fluid supply line 2441 of the second process chamber 2400 is stored, and a third tank 3300 in which the heating fluid to be provided to the fluid injection line 2451 of the second process chamber 2400 is stored.

The fluid from the first tank 3100 may be pumped by a pump 3101, and may be provided to the nozzle 2333 while being in a state in which foreign substances are removed by a filter 3102. The fluid from the first tank 3100 may optionally be heated by a heater 3103.

The processing fluid may be stored in the second tank 3200 while being in the liquid state. Since a volume of carbon dioxide, which is the processing fluid, in the liquid state is smaller than a volume of carbon dioxide in the gaseous state, more carbon dioxide may be stored in the second tank 3200. Carbon dioxide from the second tank 3200 may be supplied to a supply tank 3210. A pump 3201 and a condenser 3202 may be disposed between the second tank 3200 and the supply tank 3210, so that carbon dioxide may be pumped to the supply tank 3210 from the second tank 3200. Further, carbon dioxide converted into the gaseous state may be converted into the liquid state again due to decrease in pressure or the like. The supply tank 3210 may be configured such that the supply tank 3210 is capable of heating and pressing carbon dioxide that is introduced therein. Carbon dioxide that is introduced into the supply tank 3210 may be provided to the fluid supply line 2441 while being converted into the gaseous state due to the heating action and the pressing action of the supply tank 3210. In an embodiment, carbon dioxide that is introduced into the supply tank 3210 may be heated to a temperature equal to or more than the critical temperature and may be pressed to a pressure equal to or more than the critical pressure, so that carbon dioxide may be provided to the fluid supply line 2441 while being in the supercritical state.

The substrate processing apparatus according to an embodiment of the present disclosure may further include a control unit. The control unit may control the operation of all or part of the substrate processing apparatus according to an embodiment of the present disclosure. The control unit may associate various information in the substrate processing apparatus according to an embodiment of the present disclosure, and may perform an operation processing for the information, so that the control unit may control components of the substrate processing apparatus according to an embodiment of the present disclosure. For example, the control unit may monitor and control the flow rate of the processing fluid that is supplied by the fluid supply unit 2440, the temperature and the flow rate of the heating fluid that is injected by the supply line heating unit 2450, and the temperature and the humidity of the processing space 2411, so that the efficiency of the supercritical drying process may be increased. By using software, hardware, or a combination thereof, such a control unit may be realized as a computer or a device similar to the computer.

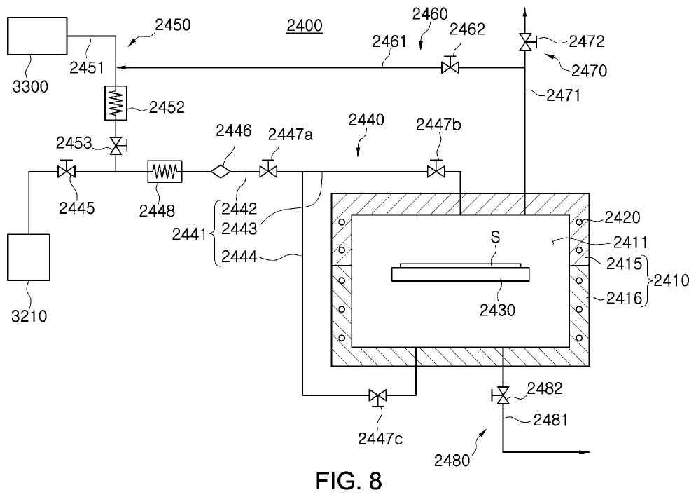

FIGS. 7 and 8 are views schematically illustrating configurations of respective modification examples of the second process chamber 2400 of the substrate processing apparatus according to an embodiment of the present disclosure.

Compared to the example of the second process chamber 2400 illustrated in FIG. 4, the modification example of the second process chamber 2400 illustrated in FIG. 7 has the same configuration and the same operation, but has only one difference that the modification example of the second process chamber 2400 illustrated in FIG. 7 further includes a supply line heater 2448 which is for heating the processing fluid that flows along the fluid supply line 2441.

The supply line heater 2448 is provided on the main line 2442 of the fluid supply line 2441. The supply line heater 2448 is disposed on the main line 2442 at a downstream side with respect to a portion to which the fluid supply line 2451 is connected.

The processing fluid that is supplied to the processing space 2411 along the fluid supply line 2441 may be heated by the supply line heater 2448, so that the creation time of the supercritical atmosphere may further be reduced. For example, when the processing fluid is supplied to the processing space 2411 while being in the supercritical state, the temperature of the processing fluid may be prevented from being dropped to the temperature below the critical temperature during the supplying process. Further, when the processing fluid is supplied to the processing space 2411 while being in the gaseous state, the temperature of the processing fluid may be increased to a temperature equal to or more than the critical temperature by heating the processing fluid. In addition, according to the supply line heater 2448, at the time when the processing fluid in the processing space 2411 is converted into the gaseous state from the supercritical state, particles in which the organic solvent remaining in the processing space 2411 in a state dissolved by the processing fluid condenses and falls on the substrate may be minimized.

The supply line heater 2448 may be operated without stopping the supply line heater 2488 in the idle mode. Therefore, in the idle mode, the heating fluid that is injected into the fluid supply line 2441 may be heated again by the supply line heater 2448. Accordingly, the temperature drop of the heating fluid in which the temperature thereof is increased may be suppressed. In addition, during the supercritical drying process mode, the heating temperature of the supply line heater 2448 may be maintained relatively constant. For example, the processing fluid that processes the first substrate may be heated to a relatively high temperature by the supply line heater 2448, and the processing fluid that processes the substrate after the second substrate since the processing of the substrate is repeated may be heated to a relatively low temperature by the supply line heater 2448 due to an output limit or the like of the supply line heater 2448. However, in the idle mode, when the heating fluid that is injected into the fluid supply line 2441 is heated by the supply line heater 2448 so that the heating temperature of the supply line heater 2448 is relatively lowered, the difference between the temperature of the processing fluid that processes the first substrate and the temperature of the processing fluid that processes the substrate after the second substrate is largely reduced, so that the substrate processing condition may be maintained more consistently.

Compared to the example of the second process chamber 2400 illustrated in FIG. 4 and to the modification example of the second process chamber 2400 illustrated in FIG. 7, the modification example of the second process chamber 2400 illustrated in FIG. 8 has the same configuration and the same operation, but has only one difference that the modification example of the second process chamber 2400 illustrated in FIG. 8 further includes a fluid collect unit 2460 collecting the heating fluid in which the temperature thereof is increased from the processing space 2411 to the supply line heating unit 2450.

According to the fluid collect unit 2460, the heating fluid which is injected into the fluid supply line 2441 from the supply line heating unit 2450 and which is introduced into the processing space 2411 may be circulated in a collecting manner. The fluid collect unit 2460 may include a fluid collect line 2461 that connects the supply line heating unit 2450 to the processing space 2411. The fluid collect line 2461 has a first side connected to the vent line 2471 at the upstream side with respect to the vent line opening and closing valve 2472, and has a second side connected to the fluid injection line 2451 at the upstream side with respect to the injection line heater 2452. Therefore, the heating fluid may be collected to the fluid injection line 2451 from the processing space 2411 through the vent line 2471. The collected heating fluid may be heated by the injection line heater 2452, so that the heating fluid may be injected into the fluid supply line 2441 while being in a state in which the temperature thereof is increased. Meanwhile, the fluid collect unit 2460 may further include a collect line opening and closing valve 2642 provided on the fluid collect line 2461, the collect line opening and closing valve 2642 opening and closing the fluid collect line 2461 and adjusting the flow rate of the heating fluid that is collected along the fluid collect line 2461.

While the present disclosure has been described above, the present disclosure is not limited to the disclosed embodiment and the accompanying drawings, and those skilled in the art may variously modify the present disclosure without departing from the technical features of the present disclosure. In addition, the technical features described in the embodiment of the present disclosure may be independently carried out or two or more technical features may be combined.

What is claimed is:

1. A substrate processing apparatus comprising:
a chamber body providing a processing space for drying a substrate with a drying fluid in a supercritical state;
a substrate support chuck supporting the substrate in the processing space;
a fluid supply unit comprising a fluid supply line configured to supply the drying fluid to the processing space; and
a supply line heating unit configured to heat the fluid supply line.

2. The substrate processing apparatus of claim 1,
wherein the supply line heating unit is configured to heat a heating fluid therein and heat the fluid supply line using the heating fluid.

3. The substrate processing apparatus of claim 2,
wherein the supply line heating unit is configured to supply the heating fluid to the fluid supply line to heat the fluid supply line.

4. The substrate processing apparatus of claim 3,
wherein the heating fluid comprises an inert gas.

5. The substrate processing apparatus of claim 3,
wherein the heating fluid comprises an inert gas having a thermal conductivity higher than a thermal conductivity of the drying fluid.

6. The substrate processing apparatus of claim 3, further comprising:
a controller configured to cause, in an idle mode, the supply line heating unit to heat the heating fluid and the fluid supply unit to supply the heating fluid to the processing space along the fluid supply line.

7. The substrate processing apparatus of claim 6, further comprising:
a vent line connected to the processing space of the chamber body and configured to release the heating fluid from the processing space; and
a fluid collect line connecting the vent line to the supply line heating unit and configured to collect the heating fluid introduced into the processing space to the supply line heating unit.

8. The substrate processing apparatus of claim 3,
wherein the supply line heating unit comprises:
a fluid injection line configured to inject the heating fluid into the fluid supply line; and
an injection line heater configured to heat the heating fluid that flows along the fluid injection line.

9. The substrate processing apparatus of claim 8,
wherein the fluid supply unit further comprises a supply line heater configured to heat the drying fluid that flows along the fluid supply line.

10. The substrate processing apparatus of claim 9,
wherein the supply line heater is provided on the fluid supply line at a downstream side with respect to a portion of the fluid supply line to which the fluid injection line is connected.

11. The substrate processing apparatus of claim 10,
wherein the fluid supply unit further comprises a filter that is provided in the fluid supply line at the downstream side thereof with respect to a portion of the fluid supply line to which the fluid injection line is connected.

12. The substrate processing apparatus of claim 9,
wherein the supply line heater is configured to heat the drying fluid to a temperature equal to or more than a critical temperature of the drying fluid.

13. A substrate processing apparatus comprising:
a chamber body providing a processing space for drying a substrate with a drying fluid in a supercritical state;
a chamber heater configured to heat the processing space to a temperature equal to or more than a critical temperature of the drying fluid;
a substrate support unit supporting the substrate in the processing space;
a fluid supply unit which has a fluid supply line that is configured to supply the drying fluid to the processing space and which has a filter and a supply line opening and closing valve that are separately provided on the fluid supply line;
a vent unit connected to the processing space; and
a supply line heating unit which has a fluid injection line that is configured to inject a heating fluid into the fluid supply line and which has an injection line heater and an injection line opening and closing valve that are separately provided on the fluid injection line, in which the fluid injection line is connected on the fluid supply line at an upstream side with respect to the filter,
wherein the supply line heating unit is configured to be operated so that the fluid supply line is heated by allowing the heating fluid in which a temperature thereof is increased in an idle mode to flow to the fluid supply line, and the fluid supply unit is configured such that the supply line opening and closing valve is opened so that the heating fluid in which the temperature thereof is increased in the idle mode is capable of being supplied to the processing space along the fluid supply line.

14. The substrate processing apparatus of claim 13, wherein the fluid supply unit further comprises a supply line heater configured to heat the drying fluid that flows along the fluid supply line to a temperature equal to or more than the critical temperature.

15. The substrate processing apparatus of claim 14, wherein the fluid supply line comprises:
a main line;
a first branch line which is branched from the main line and which supplies the drying fluid to an upper portion of the processing space; and
a second branch line which is branched from the main line and which supplies the drying fluid to a lower portion of the processing space,
the filter is disposed on the main line, and the supply line opening and closing valve comprises a plurality of supply line opening and closing valves respectively disposed on the main line, the first branch line, and the second branch line, and
the supply line heater is provided on the main line between the filter and a portion to which the fluid injection line is connected, and is configured to heat the heating fluid in the idle mode.

16. The substrate processing apparatus of claim 13, further comprising a fluid collect unit configured to collect the heating fluid in which the temperature thereof is increased in the idle mode to the supply line heating unit from the processing space.

17. A substrate processing method of drying a substrate in a processing space of a chamber body with a drying fluid in a supercritical state, the substrate processing method comprising:
performing a first process in which a fluid supply line connected to the processing space is heated in an idle mode; and
performing a second process in which a pressure of the processing space is increased by supplying the drying fluid to the processing space through the fluid supply line and the substrate is dried in a supercritical process mode.

18. The substrate processing method of claim 17,
wherein, in the first process, the fluid supply line is heated by a heating fluid flowing through the fluid supply line, thereby increasing a temperature of the fluid supply line.

19. The substrate processing method of claim 18,
wherein, in the first process, the fluid supply line in an open state, and the heating fluid flowing through the fluid supply line is supplied to the processing space.

20. The substrate processing method of claim 19,
wherein, in the first process, a temperature of the heating fluid is determined on the basis of at least one of a temperature of the fluid supply line and a temperature of the processing space.
